(19) United States
(12) Patent Application Publication
(10) Pub. No.: US 2025/0332753 A1
(43) Pub. Date: Oct. 30, 2025

(54) DUMMY REMOVAL APPARATUS AND METHOD FOR MANUFACTURING DISPLAY DEVICE

(71) Applicant: Samsung Display Co., LTD., Yongin-si (KR)

(72) Inventors: Jong Hee LIM, Yongin-si (KR); Sang Sun HAN, Yongin-si (KR); Eun Su JUN, Yongin-si (KR); Jung Bin KIM, Yongin-si (KR); Hyoung Joo KIM, Yongin-si (KR); Il Young JEONG, Yongin-si (KR)

(73) Assignee: Samsung Display Co., LTD., Yongin-si (KR)

(21) Appl. No.: 18/938,685

(22) Filed: Nov. 6, 2024

(30) Foreign Application Priority Data
Apr. 29, 2024 (KR) 10-2024-0056575

(51) Int. Cl. B26F 3/00; B29D 11/00; H01L 25/16

(52) U.S. Cl. CPC B26F 3/002; B29D 11/00644; B29D 11/00932; H01L 25/167

(57) ABSTRACT

A dummy removal apparatus for manufacturing a display device, includes: a support plate; a gripper disposed on a side of the support plate; and a presser disposed on another side of the support plate, wherein the gripper includes a body and a clamp disposed on the body, the clamp includes: a lever rotatably connected to a side of the body; and a stopper disposed on another side of the body, and in case that the lever rotates toward the stopper, an end portion of the lever and an end portion of the stopper face each other.

### CROSS-REFERENCE TO RELATED APPLICATION(S)

This application claims priority to and benefits of Korean Patent Application No. 10-2024-0056575 under 35 U.S.C. § 119, filed on Apr. 29, 2024, in the Korean Intellectual Property Office, the entire contents of are incorporated herein by reference.

### BACKGROUND

### 1. Technical Field

Embodiments relate to a dummy removal apparatus for manufacturing a display device, particularly, to a dummy removal apparatus for manufacturing a display device, capable of minimizing the outflow of an adhesive layer, and a dummy removal method using the dummy removal apparatus.

### 2. Description of the Related Art

The importance of display devices is increasing along with the development of multimedia. In response, various types of display devices such as liquid crystal display (LCD) devices and organic light-emitting display devices are being used.

### SUMMARY

Aspects of the disclosure provide a dummy removal apparatus for manufacturing a display device, capable of minimizing the outflow of the adhesive layer may be minimized, and a dummy removal method using the dummy removal apparatus.

However, embodiments are not limited to those set forth herein. The above and other embodiments will become more apparent to one of ordinary skill in the art to which the disclosure pertains by referencing the detailed description of the disclosure given below.

According to an aspect of the disclosure, a dummy removal apparatus for manufacturing a display device, may include: a support plate; a gripper disposed on a side of the support plate; and a presser disposed on another side of the support plate, wherein the gripper may include a body and a clamp disposed on the body, the clamp may include: a lever rotatably connected to a side of the body; and a stopper disposed on another side of the body, and in case that the lever rotates toward the stopper, an end portion of the lever and an end portion of the stopper may face each other.

The gripper may further include a separator disposed on a side of the stopper.

The separator may include: a first extension part; a second extension part disposed facing the first extension part; and a connecting part connecting the first and second extension parts.

The lever may be rotatably connected to the body between the first and second extension parts.

The gripper may further include a first separator and a second separator facing each other on a side of the stopper.

The clamp may further include a link having a side connected to the body via a rotating shaft and another side connected to the lever.

The presser may include: a pusher; a lower body connected to the pusher; a middle body disposed on the lower body and connected to the support plate; an upper body on the middle body; and a pressure providing part disposed between the upper body and the lower body, penetrating the middle body, and connecting the upper body and the lower body.

The pressure providing part may include: a housing having an end portion connected to the upper body and another end facing the lower body through the middle body; and a movable part having an end portion disposed in the housing and another end connected to the lower body.

The pusher may be rotatably connected to the lower body via a rotating shaft.

The lever may be connected to the body via its rotating shaft, a rotating shaft of the pusher may be connected to the lower body, and the rotating shaft of the lever and the rotating shaft of the pusher may intersect each other.

The lever may be connected to the body via its rotating shaft, a rotating shaft of the pusher may be connected to the lower body, and the rotating shaft of the lever and the rotating shaft of the pusher may be parallel to each other.

The pusher may have a cylindrical shape.

The presser may further include a sensor module that detects changes in a distance between the middle body and the lower body.

The sensor module may include: a sensor connected to the middle body; and a blocking part having a side connected to the lower body and another side extending toward a light-emitting part and a light-receiving part of the sensor.

The lever may have a rotation range of 0 to 90 degrees.

The lever may have an L-shape.

An end portion of the lever and an end portion of the stopper facing each other may have an uneven pattern.

The lever may include a plurality of finger parts.

In case that the lever rotates toward the stopper, end portions of the finger parts of the lever and an end portion of the stopper may face each other.

According to another aspect of the disclosure, a dummy removal apparatus for manufacturing a display device, may include: a support plate; a gripper disposed on a side of the support plate; and a presser disposed on another side of the support plate, wherein the gripper may include a body and a clamp disposed on the body, the clamp includes: a lever connected to the body and moving in a rectilinear direction; and a stopper disposed on another side of the body, and in case that the lever rises toward the stopper, an end portion of the lever and an end portion of the stopper may face each other.

According to another aspect of the disclosure, a dummy removal method using a dummy removal apparatus for manufacturing may include a robot arm including a support plate, a gripper disposed on a side of the support plate and including a body and a clamp disposed on the body, the clamp including: a lever rotatably connected to a side of the body, and a stopper disposed on another side of the body, and a presser disposed on another side of the support plate, the dummy removal method including: positioning the robot arm on a stage where a base panel is disposed; lowering the robot arm toward the base panel to bring the presser into contact with a display panel of the base panel; rotating the lever toward the stopper to grip a dummy of the base panel between the lever and the stopper via the clamp; and raising the robot arm to separate the display panel and the dummy, in case that the display panel is pressed by the presser.

The dummy removal method may further include: before the raising the robot arm, horizontally moving the robot arm in a direction intersecting a direction in which to raise the robot arm, in case that the dummy is gripped.

The robot arm may include a plurality of robot arms, and at least two of the robot arms may move in different horizontal directions.

According to the aforementioned and other embodiments, the outflow of an adhesive layer may be minimized. Therefore, defects caused by the outflow of the adhesive layer during the manufacture of a display device may be minimized.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail exemplary embodiments thereof with reference to the attached drawings, in which:

FIG. 1 is a schematic plan view of a display panel according to an embodiment;

FIG. 2 is a schematic cross-sectional view taken along line I-I′ of FIG. 1;

FIG. 3 is a schematic perspective view of a dummy removal apparatus for manufacturing a display device according to an embodiment;

FIG. 4 is a schematic perspective view of the dummy removal apparatus of FIG. 3, including first through fourth robot arms and a stage;

FIG. 5 is a schematic side view of the dummy removal apparatus of FIG. 4 as viewed in a Y-axis direction;

FIG. 6 is a schematic perspective view of a first robot arm 101 according to an embodiment;

FIG. 7 is a schematic side view of the first robot arm 101 of FIG. 6 as viewed in the Y-axis direction;

FIGS. 8 through 12 illustrate a dummy removal operation of a first robot arm 101 according to an embodiment;

FIG. 13 illustrates a dummy removal method of a dummy removal apparatus for manufacturing a display device according to an embodiment;

FIG. 14 illustrates a dummy removal method of a dummy removal apparatus for manufacturing a display device according to an embodiment;

FIG. 15 illustrates a dummy removal method of a dummy removal apparatus for manufacturing a display device according to an embodiment;

FIG. 16 is a schematic perspective view of a first robot arm according to an embodiment;

FIGS. 17 and 18 are schematic rear views of the first robot arm of FIG. 16 as viewed in a Z-axis direction;

FIG. 19 is a schematic perspective view of a first robot arm according to an embodiment;

FIGS. 20 and 21 are schematic rear views of the first robot arm of FIG. 19 as viewed in the Z-axis direction;

FIG. 22 is a schematic side view of a clamp according to an embodiment; and

FIG. 23 is a schematic side view of a first robot arm according to another embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Embodiments will hereinafter be described with reference to the attached drawings. Meanwhile, “X,” “Y,” and “Z” in each drawing represent X-, Y-, and Z-axis directions, respectively.

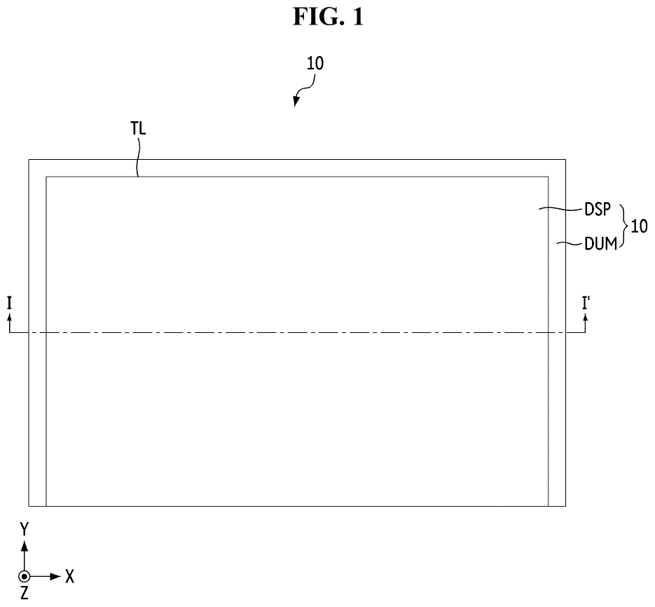

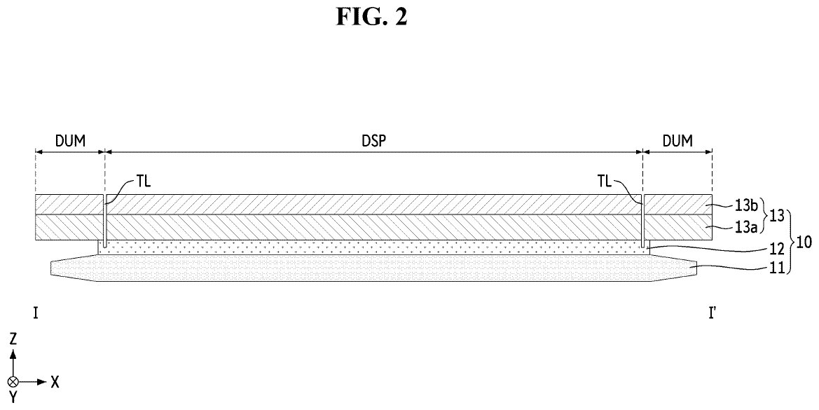

FIG. 1 is a schematic plan view of a display panel DSP according to an embodiment, and FIG. 2 is a schematic cross-sectional view taken along line I-I′ of FIG. 1.

Referring to FIGS. 1 and 2, a base panel 10 may include a substrate 11, an adhesive layer 12, and a polarizing member 13, which are stacked in the Z-axis direction.

A thin-film transistor, a light-emitting element, an encapsulation layer, and the like may be disposed on the substrate 11. For example, the thin-film transistor, the light-emitting element, and the encapsulation layer may be disposed between the substrate 11 and the adhesive layer 12. The substrate 11 may include glass.

The adhesive layer 12 may be disposed on the substrate 11. For example, the adhesive layer 12 may be disposed between the substrate 11 and the polarizing member 13. The adhesive layer 12 may bond the substrate 11 and the polarizing member 13 together. The adhesive layer 12 may include a pressure-sensitive adhesive (PSA).

The polarizing member 13 may be disposed on the adhesive layer 12. The polarizing member 13 may include a polarizing layer 13a and a protective film 13b. The polarizing layer 13a may be disposed between the adhesive layer 12 and the protective film 13b.

The base panel 10 may be a display panel DSP, which is cut and separated into each cell from a mother substrate. The base panel 10 may be processed into a desired shape by a laser device. For example, the laser device may draw a laser beam along a virtual processing line TL formed on the base panel 10. The portion with its three sides surrounded by the processing line TL may be the display panel DSP (e.g., a processed display panel DSP), and the portion surrounding the processing line TL may be a dummy DUM to be separated from the processed base panel 10. As the dummy DUM is removed from the base panel 10, the display panel DSP may be manufactured. The dummy DUM may have a “[” shape, as depicted in FIG. 1. A side of the dummy DUM may extend in the Y-axis direction, and another side of the dummy DUM may extend in the X-axis direction.

The processing line TL may have a depth that extends through the polarizing member 13 and partially into the adhesive layer 12 to completely cut the polarizing member 13. For example, the adhesive layer 12 may be half-cut to prevent damage to the substrate 11 while completely cutting the polarizing member 13. Accordingly, even after the laser beam is irradiated onto the base panel 10 along the processing line TL, the dummy DUM and the display panel DSP may remain attached to each other, rather than being separated, due to the half-cut adhesive layer 12.

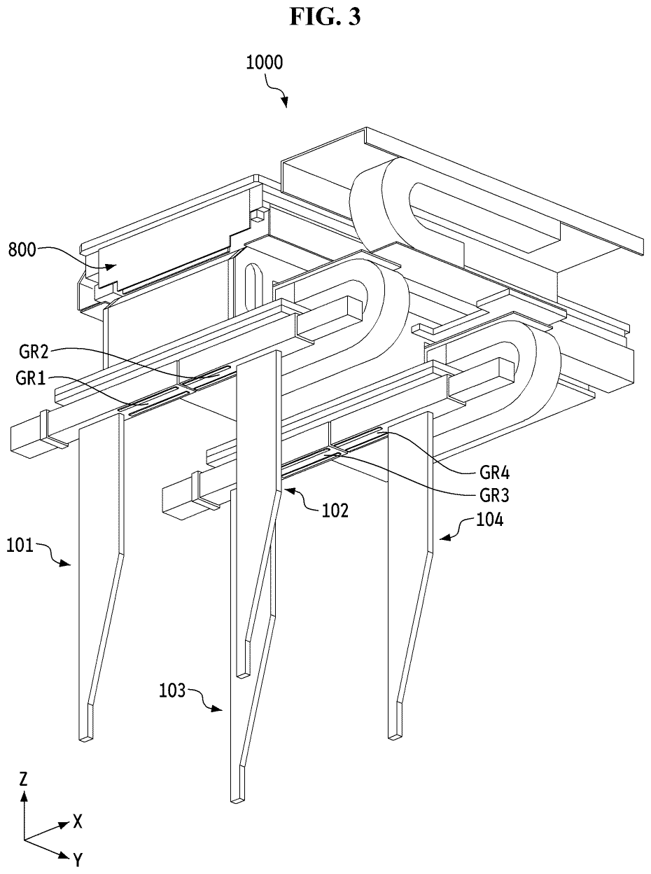

The dummy DUM attached to the base panel 10 by the half-cut adhesive layer 12 may be removed by, for example, a dummy removal apparatus 1000 for manufacturing a display device. By removing the dummy DUM from the base panel 10 using the dummy removal apparatus 1000, a display panel DSP of a desired shape may be fabricated. The dummy removal apparatus 1000 will hereinafter be described in detail with reference to FIG. 3.

FIG. 3 is a schematic perspective view of the dummy removal apparatus 1000 for manufacturing a display device.

As shown in FIG. 3, the dummy removal apparatus 1000 may include at least one robot arm. For example, the dummy removal apparatus 1000 may include a first robot arm 101, a second robot arm 102, a third robot arm 103, and a fourth robot arm 104.

Each of the first, second, third, and fourth robot arms 101, 102, 103, and 104 may move in the X-axis direction (hereinafter the positive X-axis direction) and the opposite direction of the X-axis direction (hereinafter referred to as the negative X-axis direction). For example, the first robot arm 101 may move in the positive and negative X-axis directions along a first X-guide rail GR1, the second robot arm 102 may move in the positive and negative X-axis directions along a second X-guide rail GR2, the third robot arm 103 may move in the positive and negative X-axis directions along a third X-guide rail GR3, and the fourth robot arm 104 may move in the positive and negative X-axis directions along a fourth X-guide rail GR4.

Each of the first, second, third, and fourth robot arms 101, 102, 103, and 104 may move in the Y-axis direction (hereinafter the positive Y-axis direction) and the opposite direction of the Y-axis direction (hereinafter referred to as the negative Y-axis direction). For example, a guide block 800 may include a first Y-guide rail, a second Y-guide rail, a third Y-guide rail, and a fourth Y-guide rail. For example, the first robot arm 101 may move in the positive and negative Y-axis directions along the first Y-guide rail, the second robot arm 102 may move in the positive and negative Y-axis directions along the second Y-guide rail, the third robot arm 103 may move in the positive and negative Y-axis directions along the third Y-guide rail, and the fourth robot arm 104 may move in the positive and negative Y-axis directions along the fourth Y-guide rail.

Each of the first, second, third, and fourth robot arms 101, 102, 103, and 104 may move in the Z-axis direction (hereinafter the positive Z-axis direction) and the opposite direction of the Z-axis direction (hereinafter referred to as the negative Z-axis direction).

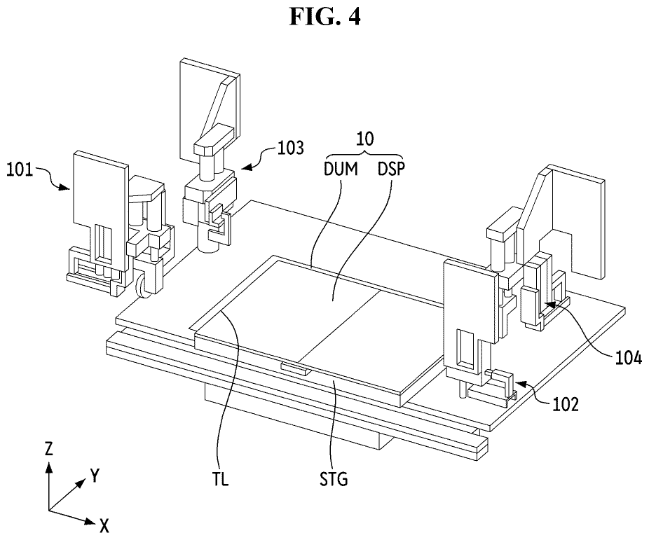

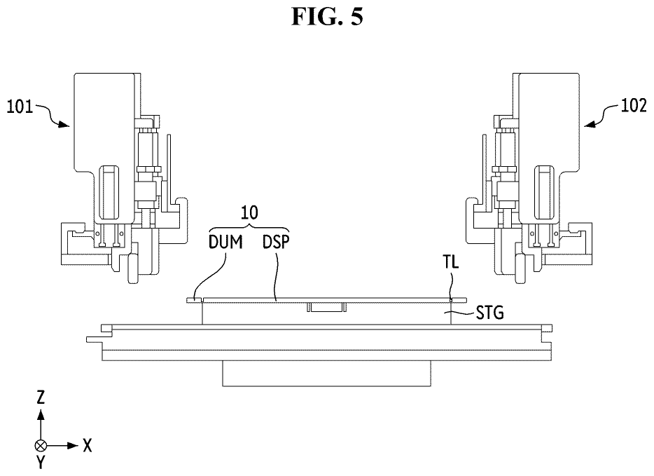

FIG. 4 is a schematic perspective view of the dummy removal apparatus 1000 of FIG. 3, including the first, second, third, and fourth robot arms 101, 102, 103, and 104 and a stage STG, and FIG. 5 is a schematic side view of the dummy removal apparatus 1000 of FIG. 4 as viewed in the positive Y-axis direction.

Referring to FIGS. 4 and 5, the dummy removal apparatus 1000 may further include the stage STG on which the substrate 11 is disposed.

The first, second, third, and fourth robot arms 101, 102, 103, and 104 may be disposed on the stage STG.

The base panel 10 may be disposed on the stage STG. For example, the base panel 10 may be disposed between the stage STG and the first, second, third, and fourth robot arms 101, 102, 103, and 104. The base panel 10 may be supported by the stage STG.

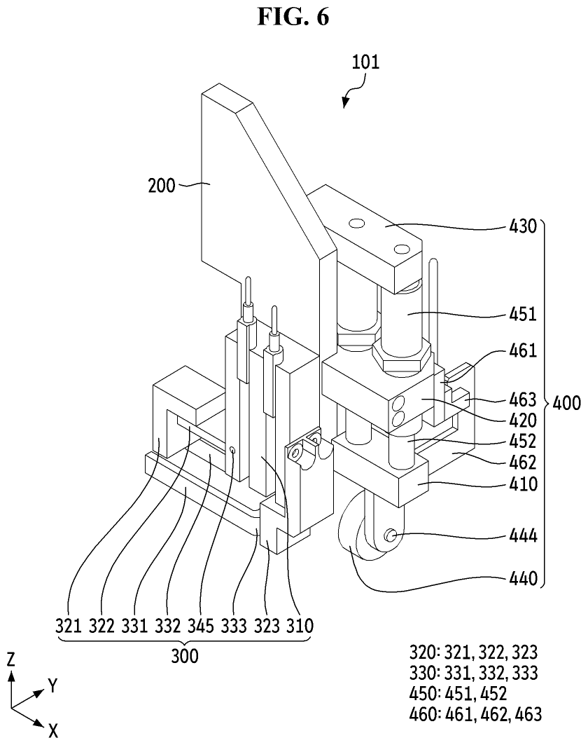

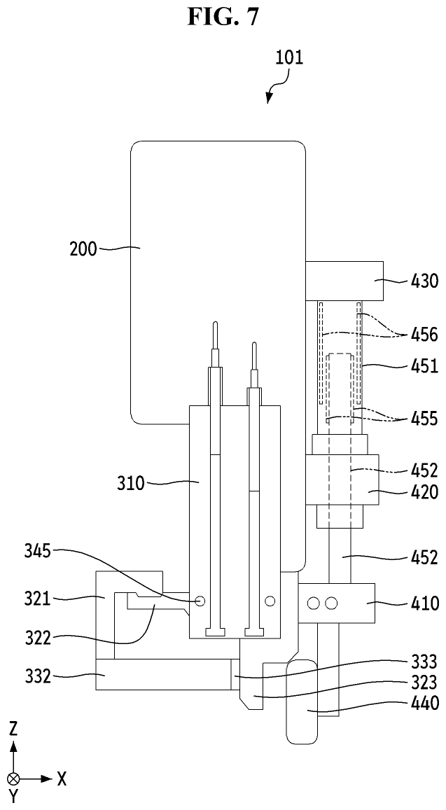

FIG. 6 is a schematic perspective view of a first robot arm 101 according to an embodiment. For example, the first robot arm 101 of FIG. 6 may be the same as the first robot arm 101 of FIG. 5. FIG. 7 is a schematic side view of the first robot arm 101 of FIG. 6 as viewed in the positive Y-axis direction.

Referring to FIGS. 6 and 7, the first robot arm 101 may include a support plate 200, a gripper 300, and a pressing part (or presser) 400.

The gripper 300 may grip the dummy DUM of the base panel 10. The gripper 300 may be disposed on a side of the support plate 200. The gripper 300 may be attached to a side of the support plate 200. The gripper 300 may be fixed to a side of the support plate 200. For example, the gripper 300 may be supported by the support plate 200.

The pressing part 400 may press the display panel DSP of the base panel 10. For example, during the operation of removing the dummy DUM of the base panel 10, the pressing part 400 may press the display panel DSP to prevent the display panel DSP from moving. For example, in case that the gripper 300 grips the dummy DUM of the base panel 10 and moves in the positive Z-axis direction, the pressing part 400 may press the display panel DSP in the negative Z-axis direction to prevent the display panel DSP from being lifted in the positive Z-axis direction. The pressing part 400 may be disposed on another side of the support plate 200. The pressing part 400 may be attached to another side of the support plate 200. The pressing part 400 may be fixed to another side of the support plate 200. For example, the pressing part 400 may be supported by the support plate 200.

The gripper 300 and the pressing part 400 will hereinafter be described in further detail.

As illustrated in FIGS. 6 and 7, the gripper 300 may include a body 310, a clamp 320, and a separator 330.

The clamp 320 may grip the dummy DUM of the base panel 10. The clamp 320 may include a lever 321, a link 322, and a stopper 323 (or an opposing plate).

The link 322 may be disposed on a side of the body 310. For example, the link 322 may be rotatably connected to a side of the body 310. For example, a side of the link 322 may be connected to the body 310 via a rotating shaft 345. For example, a side of the link 322 may be connected to the body 310 via the rotating shaft 345, and another side of the link 322 may be connected to the lever 321.

The lever 321 may be connected to another side of the link 322. For example, the lever 321 may be fixed to another side of the link 322. As the link 322 rotates, the lever 321 may also rotate in the rotation direction of the link 322. The lever 321 may rotate in the range of 90 degrees. For example, the lever 321 may have a rotation range of about 0 to about 90 degrees. The lever 321 may be L-shaped.

The stopper 323 may be disposed on another side of the body 310. For example, the stopper 323 may be disposed opposite to the lever 321. The stopper 323 may be attached and fixed to another side of the body 310. An end portion of the stopper 323 may contact an end portion of the lever 321. For example, in case that the lever 321 rotates to its maximum angle (e.g., 90 degrees) toward the stopper 323 (e.g., in case that a clamp 320 is fully closed), an end portion of the lever 321 and an end portion of the stopper 323 may contact each other. In another example, in case that the lever 321 rotates to its maximum angle toward the stopper 323, an end portion of the lever 321 and an end portion of the stopper 323 may face each other with a predetermined gap therebetween. The stopper 323, together with the lever 321, may grip the dummy DUM. For example, in case that the lever 321 rotates to its maximum angle toward the stopper 323, the dummy DUM between the end portions of the lever 321 and the stopper 323 facing each other may be gripped (or clamped) by the lever 321 and the stopper 323.

The separator 330 may remove the dummy DUM attached to an end portion of the lever 321, for example, the dummy DUM separated from the base panel 10. The separator 330 may be disposed on the stopper 323. For example, the separator 330 may be attached and fixed to a side of the stopper 323. The separator 330 may be U-shaped. The separator 330 may include a first extension 331, a second extension 332, and a connecting part 333. The first and second extensions 331 and 332 may extend in the positive X-axis direction. The first and second extensions 331 and 332 may be disposed facing each other. The connecting part 333 may connect an end portion of the first extension 331 and an end portion of the second extension 332. The connecting part 333 may be attached and fixed to a side of the stopper 323. The first extension 331, the second extension 332, and the connecting part 333 may be integral with each other. The lever 321 may rotate between the first and second extensions 331 and 332. For example, as the lever 321 rotates, the lever 321 may pass through the space between the first and second extensions 331 and 332. In a state where an end portion of the lever 321 and an end portion of the stopper 323 face each other (e.g., the dummy DUM is gripped or the clamp 320 is fully closed), the dummy DUM (e.g., the dummy DUM separated from the base panel 10) may be attached to an end portion of the lever 321 by an adhesive material from the adhesive layer 12. In case that the lever 321 rotates to its maximum angle away from the stopper 323 (e.g., in case that the lever 321 rotates to fully open the clamp 320), the dummy DUM attached to the lever 321 may collide (or be pushed) with the first and second extensions 331 and 332 as the lever 321 passes between the first and second extensions 331 and 332. For example, as the lever 321 may pass between the first and second extensions 331 and 332 and the dummy DUM extends in a direction intersecting the first and second extensions 331 and 332, the dummy DUM may collide (or be pushed) with the first and second extensions 331 and 332 in case that the lever 321 passes between the first and second extensions 331 and 332. This collision may separate the dummy DUM from the lever 321.

As illustrated in FIGS. 6 and 7, the pressing part 400 may include a lower body 410, a middle body 420, an upper body 430, a pusher 440, a pressure providing part 450, and a sensor module 460.

The pusher 440 may press the display panel DSP. The pusher 440 may be connected to the lower body 410. For example, the pusher 440 may be rotatably coupled to the lower body 410. For example, the pusher 440 may be coupled to the lower body 410 via a rotating shaft 444. The pusher 440 may have a cylindrical shape. The outer surface of the pusher 440 may contact the display panel DSP. The outer surface of the pusher 440 may be formed of an elastic material. For example, the outer surface of the pusher 440 may include rubber. The pusher 440 may include ball bearings inside. The rotating shaft 444 connected to the pusher 440 and the rotating shaft 345 connected to the clamp 320 may intersect each other. For example, the rotating shaft 444 of the pusher 440 may extend in the positive X-axis direction, and the rotating shaft 345 of the clamp 320 may extend in the positive Y-axis direction. In another example, the rotating shaft 444 connected to the pusher 440 and the rotating shaft 345 connected to the clamp 320 may be parallel to each other.

The lower body 410 may support the pusher 440. The rotating shaft 444 of the pusher 440 may pass through the lower body 410 to be connected to the center portion of the pusher 440.

The middle body 420 may be disposed on the lower body 410. The middle body 420 may be connected to the support plate 200. For example, the middle body 420 may be attached and fixed to the support plate 200.

The upper body 430 may be disposed on the middle body 420. The upper body 430 and the middle body 420 may be spaced apart from each other.

The pressure providing part 450 may provide pressure to the pusher 440 through the lower body 410. For example, the pressure providing part 450 may provide pressure to the pusher 440 through the restoring force in the negative Z-axis direction after being compressed in the positive Z-axis direction. For example, the pressure providing part 450 may buffer the movement of the pusher 440 (e.g., movement in the positive and negative Z-axis directions). The pressure providing part 450 may be disposed between the upper body 430 and the lower body 410. For example, the pressure providing part 450 may pass through the middle body 420. For example, the pressure providing part 450 may pass through the middle body 420 between the upper body 430 and the lower body 410. For example, the pressure providing part 450 may be disposed between the upper body 430 and the lower body 410, and may pass through the middle body 420 to be connected the upper body 430 and the lower body 410 to each other. The pressure providing part 450 may include a housing 451 and a movable part 452. The housing 451 may pass through the middle body 420. An end portion of the housing 451 may be attached and fixed to the upper body 430, and the outer circumferential surface of the housing 451 may be attached and fixed to the inner wall of the through hole of the middle body 420. For example, an end portion of the housing 451 may be connected to the upper body 430, and another end portion of the housing 451 may pass through the middle body 420 and face the lower body 410. The movable part 452 may be disposed at another end portion of the housing 451. An end portion of the movable part 452 may be attached and fixed to the lower body 410. For example, an end portion of the movable part 452 may be disposed in the housing 451, and another end portion of the movable part 452 may be connected to the lower body 410. The movable part 452 may move in the positive and negative Z-axis directions along the internal movement path of the housing 451. In case that the movable part 452 moves in the positive Z-axis direction (e.g., in case that the movable part 452 contracts), the lower body 410 and the pusher 440 connected to the lower body 410 may rise in the positive Z-axis direction, thereby reducing the distance between the middle body 420 and the lower body 410. In case that the movable part 452 moves in the negative Z-axis direction (e.g., in case that the movable part 452 expands), the lower body 410 and the pusher 440 connected to the lower body 410 may descend (or be lowered) in the negative Z-axis direction, thereby increasing the distance between the middle body 420 and the lower body 410. To apply constant pressure to the display panel DSP via the pusher 440, an elastic body such as a spring or a magnet may be disposed in the housing 451. For example, the magnet may include an inner magnet 455, which surrounds the outer surface of the movable part 452 and is connected to the movable part 452, and an outer magnet 456, which surrounds the inner magnet 455. The facing surfaces of the outer magnet 456 and the inner magnet 455 may have opposite polarities. Pressure may be provided to the movable part 452 by the repulsive force between the outer magnet 456 and the inner magnet 455.

The sensor module 460 may detect the distance (or changes in the distance) between the middle body 420 and the lower body 410. The sensor module 460 may include a sensor 461 and a blocking part 462. The sensor 461 may include an optical sensor. The sensor 461 may include a light-emitting part 463 and a light-receiving part, which are disposed to face each other. The blocking part 462 may extend from the lower body 410 and may be disposed between the light-emitting part 463 and the light-receiving part of the sensor 461. As described earlier, in case that the lower body 410 rises in the positive Z-axis direction and the blocking part 462 moves out from between the light-emitting part 463 and the light-receiving part of the sensor 461, light from the light-emitting part 463 may be incident on the light-receiving part. The sensor 461 may then detect the light and determine that the distance between the middle body 420 and the lower body 410 has decreased.

For example, the second, third, and fourth robot arms 102, 103, and 104 may have the same configuration as the first robot arm 101 illustrated in FIGS. 6 and 7.

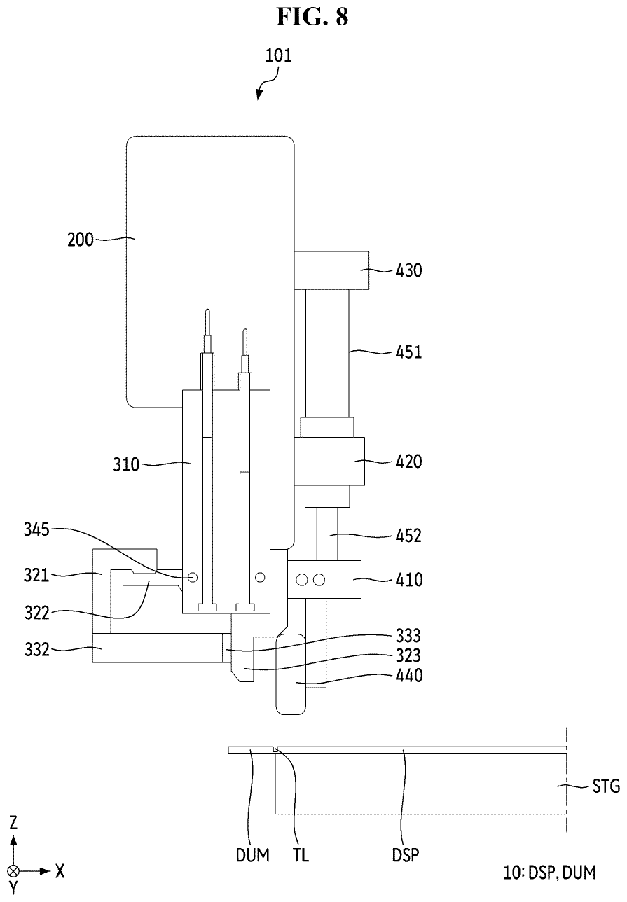

FIGS. 8 through 12 illustrate a dummy removal operation of a first robot arm 101 according to an embodiment.

Referring to FIG. 8, the first robot arm 101 may be disposed on a base panel 10.

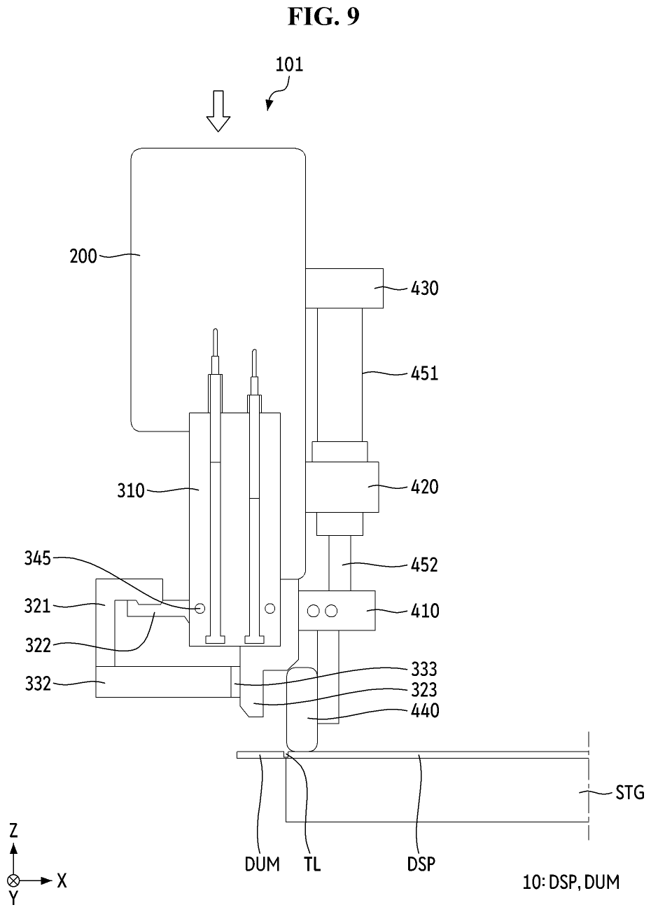

Thereafter, referring to FIG. 9, the first robot arm 101 may descend (or be lowered) in the negative Z-axis direction. For example, a pusher 440, which is disposed at the lowermost part of the first robot arm 101, may first come into contact with a display panel DSP of the base panel 10.

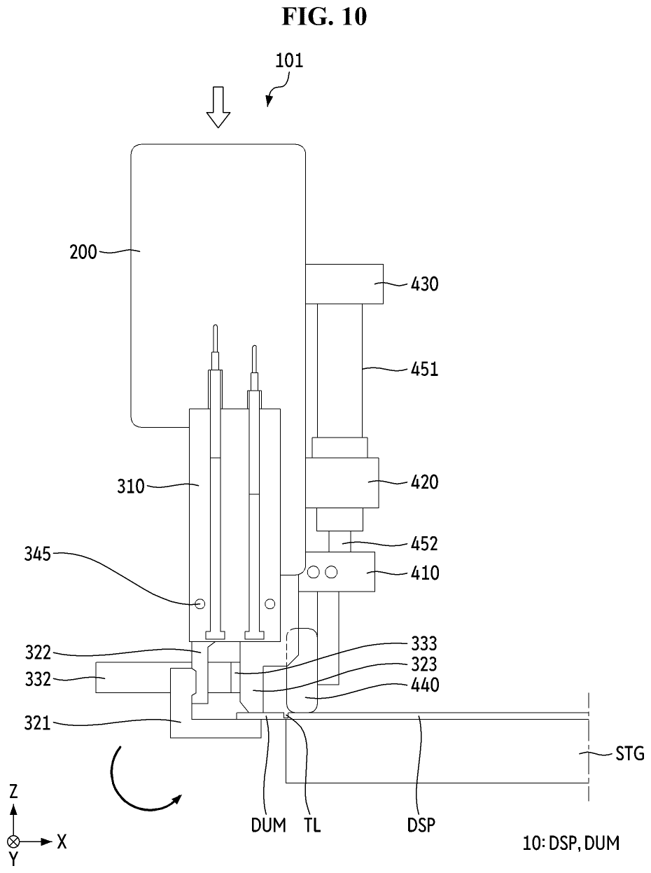

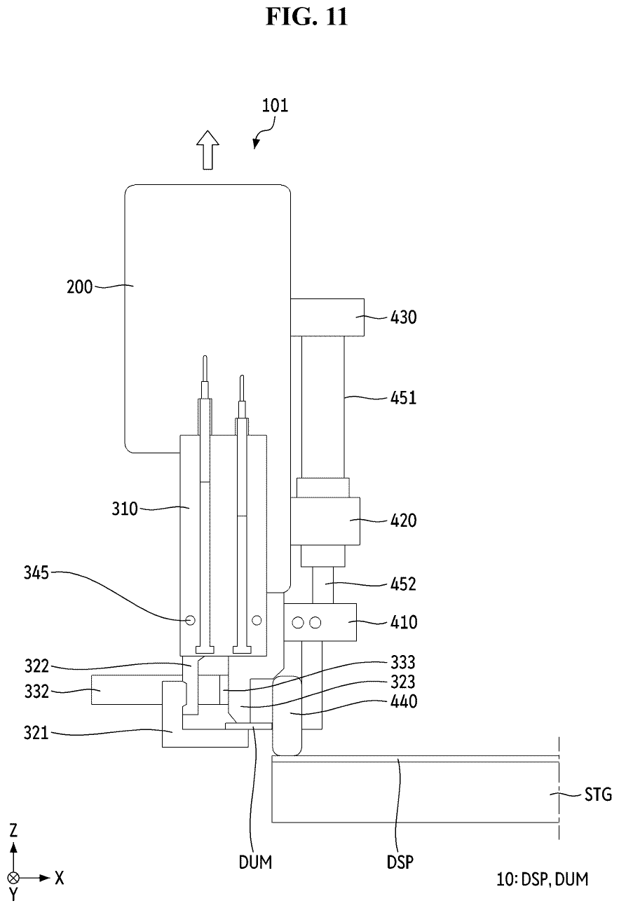

Thereafter, referring to FIG. 10, the first robot arm 101 may descend (or be lowered) further in the negative Z-axis direction, while the pusher 440 is in contact with the display panel DSP. As a result, pressure may be applied to the pusher 440 in the positive Z-axis direction. Then, a lower body 410 connected to the pusher 440 may rise, reducing the distance between the lower body 410 and a middle body 420. A sensor module 460 may detect in case that the distance between the lower body 410 and the middle body 420 reaches a preset reference distance, and may then transmit a first detection signal, as a result of the detection, to the control unit of the first robot arm 101. In response to the first detection signal, the control unit of the first robot arm 101 may operate a lever 321. For example, the lever 321 may rotate to its maximum angle toward a stopper 323. For example, the lever 321 may rotate counterclockwise to its maximum angle. As a result, a dummy DUM of the base panel 10 may be gripped (or clamped) by the lever 321 and the stopper 323. In an embodiment, after the dummy DUM is gripped as illustrated in FIG. 10, the first robot arm 101 may additionally move horizontally (e.g., in the positive X-axis direction or the negative X-axis direction) intersecting the direction (e.g., the positive or negative Z-axis direction) of vertical movement of the first robot arm 101. For example, while gripping the dummy DUM, the first robot arm 101 may move in the positive X-axis direction or the negative X-axis direction. As described later with reference to FIG. 11, the dummy DUM may be readily removed during the dummy removal process. For example, as described earlier, in case that the first robot arm 101 moves in the positive X-axis direction or the negative X-axis direction, the pusher 440 may press the display panel DSP while rotating in the positive or negative X-axis direction. Therefore, damage to the display panel DSP due to the movement of the pusher 440 may be prevented.

Thereafter, referring to FIG. 11, the first robot arm 101 may ascend (or rise) in the positive Z-axis direction while gripping the dummy DUM. For example, since the pusher 440 is still in contact with, and presses, the display panel DSP, the display panel DSP may be maintained in contact with a stage STG without being lifted in the positive Z-axis direction in case that the first robot arm 101 ascends (or rises) in the positive Z-axis direction. As the dummy DUM ascends (or rises) in the positive Z-axis direction while the display panel DSP is pressed in this manner, the dummy DUM and the display panel DSP may be readily separated. For example, by removing the dummy DUM from the base panel 10, the display panel DSP may be manufactured. As the dummy DUM is removed vertically (e.g., in the positive Z-axis direction) by the ascending motion of the first robot arm 101 in the positive Z-axis direction, the outflow of an adhesive layer 12 may be minimized. For example, since the dummy DUM is removed vertically rather than horizontally (e.g., the positive X-axis direction or the positive Y-axis direction), the horizontal outflow of the half-cut adhesive layer 12 may be prevented.

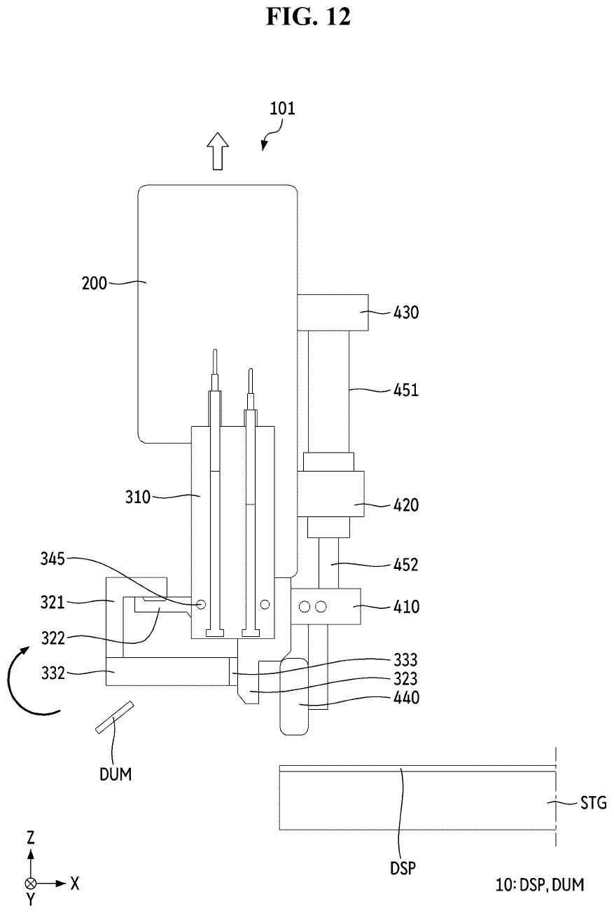

Thereafter, referring to FIG. 12, as the first robot arm 101, gripping the dummy DUM, further ascends (or rises) in the positive Z-axis direction, the contact between the pusher 440 and the display panel DSP may be released. Consequently, the pressure applied to the pusher 440 may be removed. Thereafter, the lower body 410, connected to the pusher 440, may descend (or be lowered), increasing the distance between the lower body 410 and the middle body 420, and as a result, the blocking part 462 may be disposed between a light-emitting part and the light-receiving part of the sensor 461, thereby blocking light from a light-emitting part with the blocking part 462. The sensor module 460 may then transmit a second detection signal to the control unit of the first robot arm 101. In response to the second detection signal, the control unit of the first robot arm 101 may operate the lever 321. For example, the lever 321 may rotate to its maximum angle away from the stopper 323. For example, the lever 321 may rotate clockwise to its maximum angle. Then, the gripping force of the clamp 320 may be released, and the dummy DUM may be separated from the clamp 320.

For example, even after the gripping force of the clamp 320 is released, the dummy DUM (e.g., the dummy DUM separated from the base panel 10) may remain attached to an end portion of the lever 321 due to the adhesive material from the adhesive layer 12. For example, in case that the lever 321 rotates to its maximum angle away from the stopper 323 (e.g., in case that the lever 321 rotates to fully open the clamp 320), the dummy DUM, attached to the lever 321, may collide (or be pushed) with the first and second extensions 331 and 332, as the lever 321 passes between the first and second extensions 331 and 332. This collision may separate the dummy DUM from the lever 321.

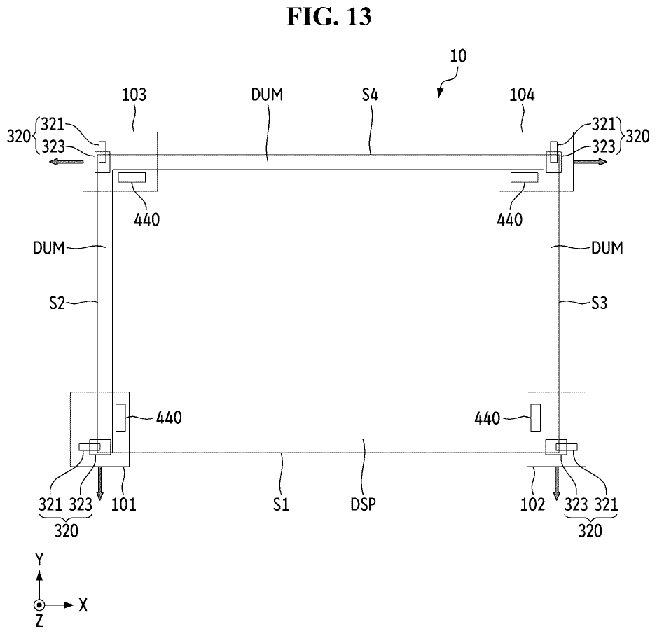

FIG. 13 illustrates a dummy removal method of a dummy removal apparatus 1000 for manufacturing a display device according to an embodiment.

Referring to FIG. 13, the dummy removal apparatus 1000 may include first, second, third, and fourth robot arms 101, 102, 103, and 104.

The first, second, third, and fourth robot arms 101, 102, 103, and 104 may have the same configuration as the first robot arm 101 depicted in FIGS. 6 and 7.

Each of the first, second, third, and fourth robot arms 101, 102, 103, and 104 may include a pusher 440 and a clamp 320. The clamp 320 may include a lever 321 and a stopper 323.

A base panel 10 may have a first corner portion defined by a bottom edge portion S1 and a left edge portion S2, a second corner portion defined by the bottom edge portion S1 and a right edge portion S3, a third corner portion defined by a top edge portion S4 and the left edge portion S2, and a fourth corner portion defined by the top edge portion S4 and the right edge portion S3.

The first robot arm 101 may be disposed at the first corner portion of the base panel 10. The first robot arm 101 may grip a dummy DUM disposed at the first corner portion. After gripping the dummy DUM at the first corner portion, the first robot arm 101 may move horizontally (e.g., in the negative Y-axis direction). For example, after gripping the dummy DUM on the first corner portion, as illustrated in FIG. 10, the first robot arm 101 may move in the negative Y-axis direction, as illustrated in FIG. 13.

The second robot arm 102 may be disposed at the second corner portion of the base panel 10. The second robot arm 102 may grip the dummy DUM disposed at the second corner portion. After gripping the dummy DUM at the second corner portion, the second robot arm 102 may move horizontally (e.g., in the negative Y-axis direction). For example, after gripping the dummy DUM at the second corner portion, as illustrated in FIG. 10, the second robot arm 102 may move in the negative Y-axis direction, as illustrated in FIG. 13.

The third robot arm 103 may be disposed at the third corner portion of the base panel 10. The third robot arm 103 may grip the dummy DUM disposed at the third corner portion. After gripping the dummy DUM at the third corner portion, the third robot arm 103 may move horizontally (e.g., in the negative X-axis direction). For example, after gripping the dummy DUM at the third corner portion, as illustrated in FIG. 10, the third robot arm 103 may move in the negative X-axis direction, as illustrated in FIG. 13.

The fourth robot arm 104 may be disposed at the fourth corner portion of the base panel 10. The fourth robot arm 104 may grip the dummy DUM disposed at the fourth corner portion. After gripping the dummy DUM at the fourth corner portion, the fourth robot arm 104 may move horizontally (e.g., in the positive X-axis direction). For example, after gripping the dummy DUM at the fourth corner portion, as illustrated in FIG. 10, the fourth robot arm 104 may move in the positive X-axis direction, as illustrated in FIG. 13.

The first, second, third, and fourth robot arms 101, 102, 103, and 104 may simultaneously grip the dummy DUM at their respective corner portions.

Thereafter, gripping the dummy DUM at their respective corner portions, the first, second, third, and fourth robot arms 101, 102, 103, and 104 may simultaneously move in their respective directions. For example, gripping the dummy DUM at their respective corner portions, the first, second, third, and fourth robot arms 101, 102, 103, and 104 may move in directions away from the display panel DSP.

Thereafter, as illustrated in FIG. 11, the first, second, third, and fourth robot arms 101, 102, 103, and 104 may simultaneously ascend (or rise) in the positive Z-axis direction while maintaining contact between their respective pushers 440 and the display panel DSP to remove the dummy DUM from the respective corner portions of the base panel 10.

Thereafter, as illustrated in FIG. 12, the first, second, third, and fourth robot arms 101, 102, 103, and 104 may further ascend (or rise) in the positive Z-axis direction to release the contact between their respective pushers 440 and the display panel DSP, thereby removing the dummy DUM attached to their respective levers 321.

Since the dummy DUM is removed vertically, the dummy DUM may be effectively removed with a smaller number of robot arms. For example, as the dummy DUM is removed by four robot arms, i.e., the first, second, third, and fourth robot arms 101, 102, 103, and 104, the area of the dummy DUM gripped by the first, second, third, and fourth robot arms 101, 102, 103, and 104 is reduced, and thus, the outflow of an adhesive layer 12 may be minimized.

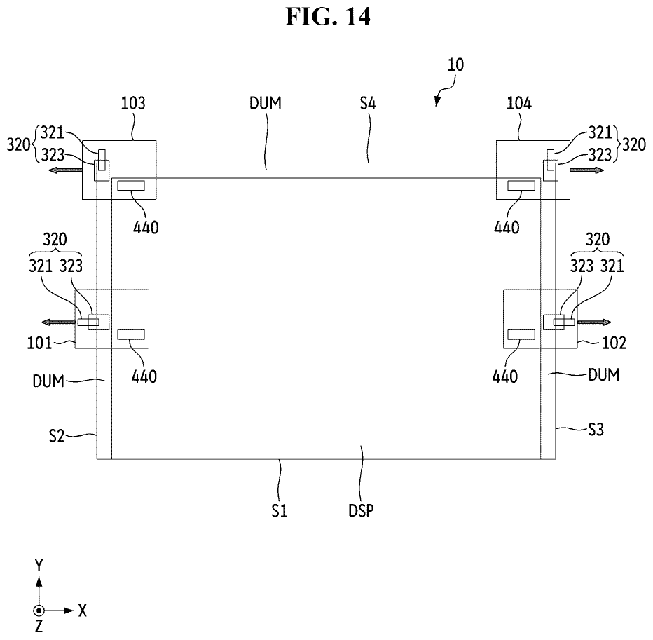

FIG. 14 illustrates a dummy removal method of a dummy removal apparatus 1000 for manufacturing a display device according to an embodiment.

Referring to FIG. 14, the dummy removal apparatus 1000 may include first, second, third, and fourth robot arms 101, 102, 103, and 104.

The first, second, third, and fourth robot arms 101, 102, 103, and 104 may have the same configuration as the first robot arm 101 depicted in FIGS. 6 and 7.

Each of the first, second, third, and fourth robot arms 101, 102, 103, and 104 may include a pusher 440 and a clamp 320. The clamp 320 may include a lever 321 and a stopper 323.

In FIG. 14, a base panel 10 may include a first corner portion defined by a bottom edge portion S1 and a left edge portion S2, a second corner portion defined by the bottom edge portion S1 and a right edge portion S3, a third corner portion defined by a top edge portion S4 and the left edge portion S2, and a fourth corner portion defined by the top edge portion S4 and the right edge portion S3.

The first robot arm 101 may be disposed on the left edge portion S2 of the base panel 10. The first robot arm 101 may grip the dummy DUM disposed on the left edge portion S2. After gripping the dummy DUM on the left edge portion S2, the first robot arm 101 may move horizontally (e.g., in the negative X-axis direction). For example, after gripping the dummy DUM on the left edge portion S2, as illustrated in FIG. 10, the first robot arm 101 may move in the negative X-axis direction, as illustrated in FIG. 14.

The second robot arm 102 may be disposed on the right edge portion S3 of the base panel 10. The second robot arm 102 may grip the dummy DUM disposed on the right edge portion S3. After gripping the dummy DUM on the right edge portion S3, the second robot arm 102 may move horizontally (e.g., in the positive X-axis direction). For example, after gripping the dummy DUM on the right edge portion S3, as illustrated in FIG. 10, the second robot arm 102 may move in the positive X-axis direction, as illustrated in FIG. 14.

The third robot arm 103 may be disposed at the third corner portion of the base panel 10. The third robot arm 103 may grip the dummy DUM disposed at the third corner portion. After gripping the dummy DUM at the third corner portion, the third robot arm 103 may move horizontally (e.g., in the negative X-axis direction). For example, after gripping the dummy DUM at the third corner portion, as illustrated in FIG. 10, the third robot arm 103 may move in the negative X-axis direction, as illustrated in FIG. 14.

The fourth robot arm 104 may be disposed at the fourth corner portion of the base panel 10. The fourth robot arm 104 may grip the dummy DUM disposed at the fourth corner portion. After gripping the dummy DUM at the fourth corner portion, the fourth robot arm 104 may move horizontally (e.g., in the positive X-axis direction). For example, after gripping the dummy DUM at the fourth corner portion, as illustrated in FIG. 10, the fourth robot arm 104 may move in the positive X-axis direction, as illustrated in FIG. 14.

The first, second, third, and fourth robot arms 101, 102, 103, and 104 may simultaneously grip the dummy DUM positioned at the respective corner portions or edge portions.

Thereafter, gripping the dummy DUM at their respective corner portions or edge portions, the first, second, third, and fourth robot arms 101, 102, 103, and 104 may simultaneously move in their respective directions. For example, gripping the dummy DUM at their respective corner portions, the first, second, third, and fourth robot arms 101, 102, 103, and 104 may move in directions away from the display panel DSP.

Thereafter, as illustrated in FIG. 11, the first, second, third, and fourth robot arms 101, 102, 103, and 104 may simultaneously ascend (or rise) in the positive Z-axis direction while maintaining contact between their respective pushers 440 and the display panel DSP to remove the dummy DUM from the respective corner portions of the base panel 10.

Thereafter, as illustrated in FIG. 12, the first, second, third, and fourth robot arms 101, 102, 103, and 104 may further ascend (or rise) in the positive Z-axis direction to release the contact between their respective pushers 440 and the display panel DSP, thereby removing the dummy DUM attached to their respective levers 321.

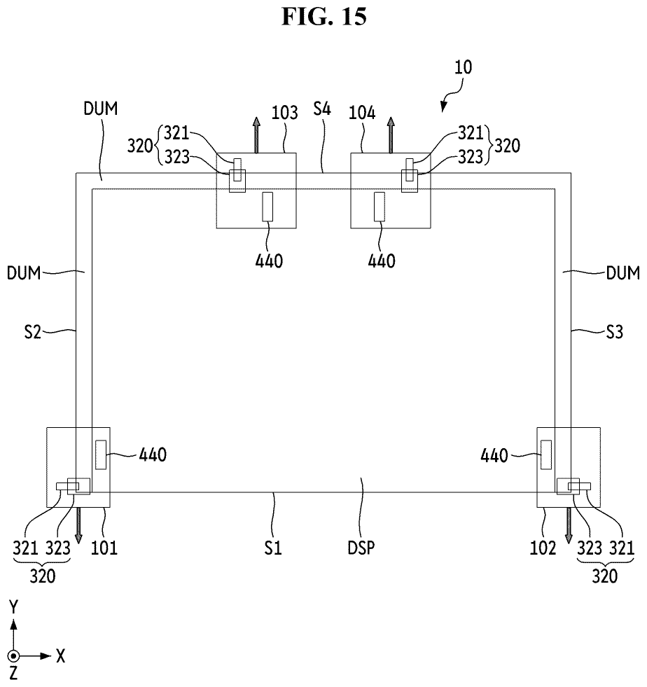

FIG. 15 illustrates a dummy removal method of a dummy removal apparatus 1000 for manufacturing a display device according to an embodiment.

Referring to FIG. 15, the dummy removal apparatus 1000 may include first, second, third, and fourth robot arms 101, 102, 103, and 104.

The first, second, third, and fourth robot arms 101, 102, 103, and 104 may have the same configuration as the first robot arm 101 depicted in FIGS. 6 and 7.

Each of the first, second, third, and fourth robot arms 101, 102, 103, and 104 may include a pusher 440 and a clamp 320. The clamp 320 may include a lever 321 and a stopper 323.

In FIG. 15, a base panel 10 may include a first corner portion defined by a bottom edge portion S1 and a left edge portion S2, a second corner portion defined by the bottom edge portion S1 and a right edge portion S3, a third corner portion defined by a top edge portion S4 and the left edge portion S2, and a fourth corner portion defined by the top edge portion S4 and the right edge portion S3.

The first robot arm 101 may be disposed at the first corner portion. The first robot arm 101 may grip the dummy DUM disposed at the first corner portion. After gripping the dummy DUM at the first corner portion, the first robot arm 101 may move horizontally (e.g., in the negative X-axis direction). For example, after gripping the dummy DUM at the first corner portion, as illustrated in FIG. 10, the first robot arm 101 may move in the positive Y-axis direction, as illustrated in FIG. 15.

The second robot arm 102 may be disposed at the second corner portion. The second robot arm 102 may grip the dummy DUM disposed at the second corner portion. After gripping the dummy DUM at the second corner portion, the second robot arm 102 may move horizontally (e.g., in the positive X-axis direction). For example, after gripping the dummy DUM at the second corner portion, as illustrated in FIG. 10, the second robot arm 102 may move in the positive Y-axis direction, as illustrated in FIG. 14.

The third robot arm 103 may be disposed on the top edge portion S4 of the base panel 10. The third robot arm 103 may grip the dummy DUM disposed on the top edge portion S4. After gripping the dummy DUM on the top edge portion S4, the third robot arm 103 may move horizontally (e.g., in the negative Y-axis direction). For example, after gripping the dummy DUM on the top edge portion S4, as illustrated in FIG. 10, the third robot arm 103 may move in the negative Y-axis direction, as illustrated in FIG. 15.

The fourth robot arm 104 may be disposed on the top edge portion S4 of the base panel 10. The fourth robot arm 104 may grip the dummy DUM disposed on the top edge portion S4. After gripping the dummy DUM on the top edge portion S4, the fourth robot arm 104 may move horizontally (e.g., in the positive Y-axis direction). For example, after gripping the dummy DUM on the top edge portion S4, as illustrated in FIG. 10, the fourth robot arm 104 may move in the positive Y-axis direction, as illustrated in FIG. 15.

The first, second, third, and fourth robot arms 101, 102, 103, and 104 may simultaneously grip the dummy DUM positioned at the respective corner portions or edge portions.

Thereafter, gripping the dummy DUM at their respective corner portions or edge portions, the first, second, third, and fourth robot arms 101, 102, 103, and 104 may simultaneously move in their respective directions. For example, gripping the dummy DUM at their respective corner portions, the first, second, third, and fourth robot arms 101, 102, 103, and 104 may move in directions away from the display panel DSP.

Thereafter, as illustrated in FIG. 11, the first, second, third, and fourth robot arms 101, 102, 103, and 104 may simultaneously ascend (or rise) in the positive Z-axis direction while maintaining contact between their respective pushers 440 and the display panel DSP to remove the dummy DUM from the respective corner portions of the base panel 10.

Thereafter, as illustrated in FIG. 12, the first, second, third, and fourth robot arms 101, 102, 103, and 104 may further ascend (or rise) in the positive Z-axis direction to release the contact between their respective pushers 440 and the display panel DSP, thereby removing the dummy DUM attached to their respective levers 321.

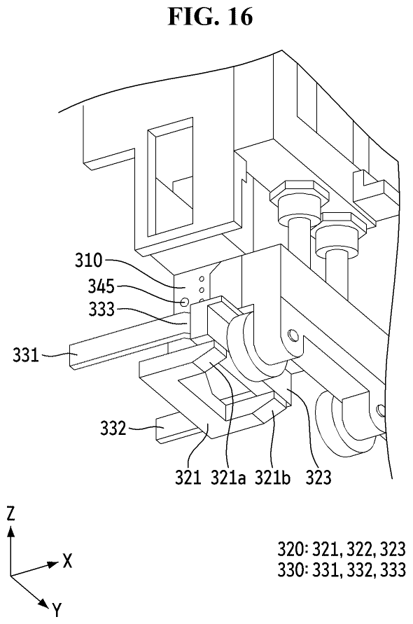

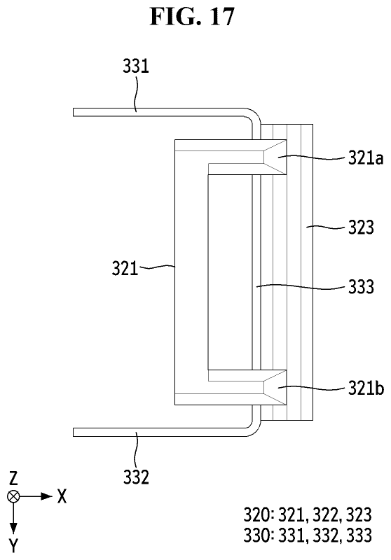

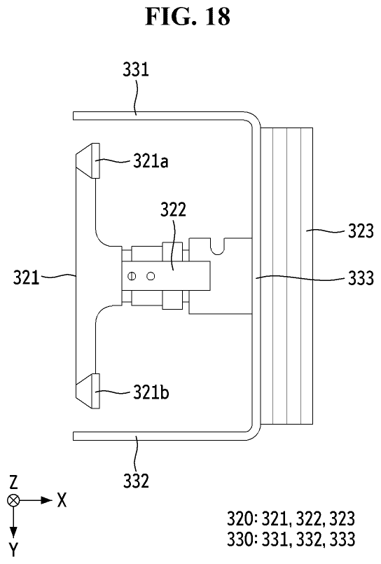

FIG. 16 is a schematic perspective view of a first robot arm 101 according to an embodiment, and FIGS. 17 and 18 are schematic rear views of the first robot arm 101 of FIG. 16 as viewed in the positive Z-axis direction. For example, FIG. 17 is a schematic rear view of the first robot arm 101 of FIG. 16 as viewed in the positive Z-axis direction in case that a clamp 320 of FIG. 16 is fully closed, and FIG. 18 is a schematic rear view of the first robot arm 101 of FIG. 16 as viewed in the positive Z-axis direction in case that the clamp 320 of FIG. 16 is fully opened.

A lever 321 may be rotatably coupled to a body 310 via a link 322. The lever 321 may include finger parts 321a and 321b. For example, the lever 321 may include first and second finger parts 321a and 321b, which are disposed to face each other. A gap may be formed between the first and second finger parts 321a and 321b.

In case that the lever 321 rotates to its maximum angle (e.g., 90 degrees) toward a stopper 323, the first and second finger parts 321a and 321b of the lever 321 may face first and second end portions, respectively, of the stopper 323. The first finger part 321a may contact the first end portion of the stopper 323, and the second finger part 321b may contact the second end portion of the stopper 323.

In case that the lever 321 rotates, the first and second finger parts 321a and 321b of the lever 321 may pass between first and second extension parts 331 and 332 of a separator 330.

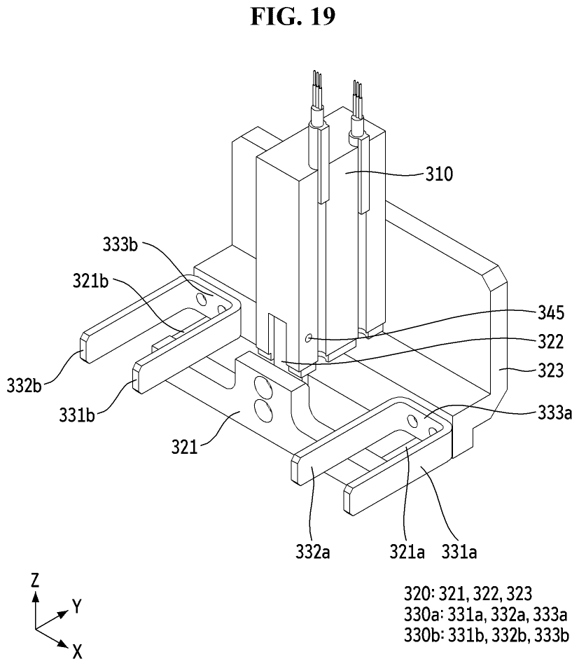

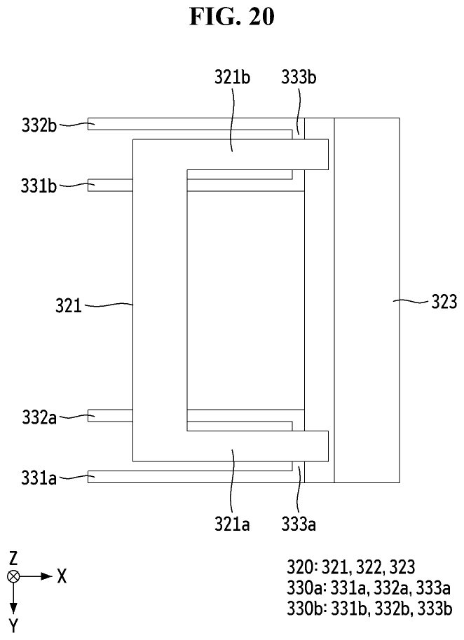

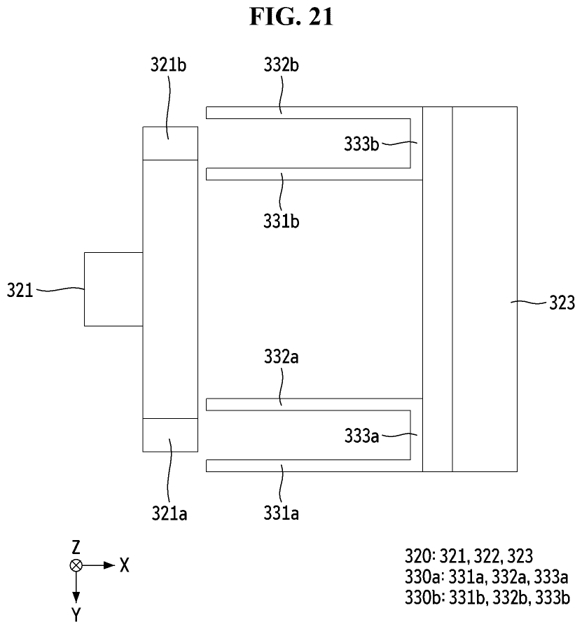

FIG. 19 is a schematic perspective view of a first robot arm 101 according to an embodiment, and FIGS. 20 and 21 are schematic rear views of the first robot arm 101 of FIG. 19 as viewed in the positive Z-axis direction. For example, FIG. 20 is a schematic rear view of the first robot arm 101 of FIG. 19 as viewed in the positive Z-axis direction in case that a clamp 320 of FIG. 19 is fully closed, and FIG. 21 is a schematic rear view of the first robot arm 101 of FIG. 19 as viewed in the positive Z-axis direction in case that the clamp 320 of FIG. 19 is fully opened.

Separators 330a and 330b may be positioned on a side of a stopper 323. For example, the separators 330a and 330b may include first and second separators 330a and 330b, which are disposed to face each other. The first separator 330a may include a first extension part 331a, a second extension part 332a, and a connecting part 333a. The connecting part 333a of the first separator 330a may connect first and second extension parts 331a and 332a of the first separator 330a. The first extension part 331a, the second extension part 332a, and the connecting part 333a of the first separator 330a may be integral with each other. The second separator 330b may include a first extension part 331b, a second extension part 332b, and a connecting part 333b. The connecting part 333b of the second separator 330b may connect first and second extension parts 331b and 332b of the second separator 330b. The first extension part 331b, the second extension part 332b, and the connecting part 333b of the second separator 330b may be integral with each other.

The lever 321 may be rotatably coupled to a body 310 via a link 322. The lever 321 may include finger parts 321a and 321b. For example, the lever 321 may include first and second finger parts 321a and 321b, which are disposed to face each other. A gap may be formed between the first and second finger parts 321a and 321b.

In case that the lever 321 rotates to its maximum angle (e.g., 90 degrees) toward the stopper 323, the first and second finger parts 321a and 321b of the lever 321 may face first and second end portions, respectively, of the stopper 323. The first finger part 321a may contact the first end portion of the stopper 323, and the second finger part 321b may contact the second end portion of the stopper 323.

In case that the lever 321 rotates, the first finger part 321a of the lever 321 may pass between the first and second extension parts 331a and 332a of the first separator 330a, and the second finger part 321b may pass between the first and second extension parts 331b and 332b of the second separator 330b.

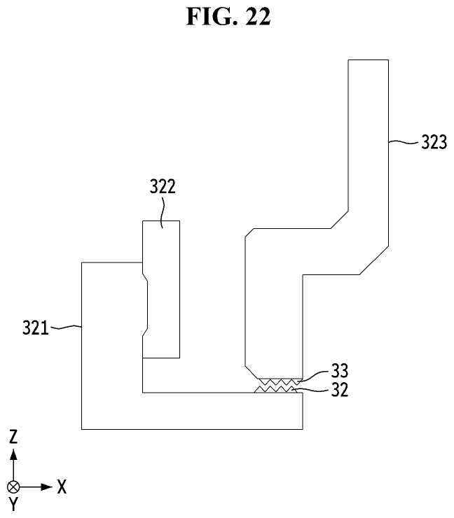

FIG. 22 is a schematic side view of a clamp 320 according to an embodiment.

Referring to FIG. 22, to improve the gripping force of the clamp 320, the end portions of a lever 321 and a stopper 323 facing each other may have unevenness patterns 32 and 33, respectively. For example, to provide the facing surfaces of the lever 321 and the stopper 323 with a high surface roughness, the facing surfaces of the lever 321 and the stopper 323 may have the unevenness patterns 32 and 33, respectively. For example, the projections of the pattern 32 on the lever 321 and the recesses of the pattern 33 on the stopper 323 may be arranged to face one another, and the recesses of the pattern 32 on the lever 321 and the projections of the pattern 33 on the stopper 323 may be arranged to face one another. The unevenness patterns 32 and 33 may be formed by, for example, thermal spraying or sandblasting.

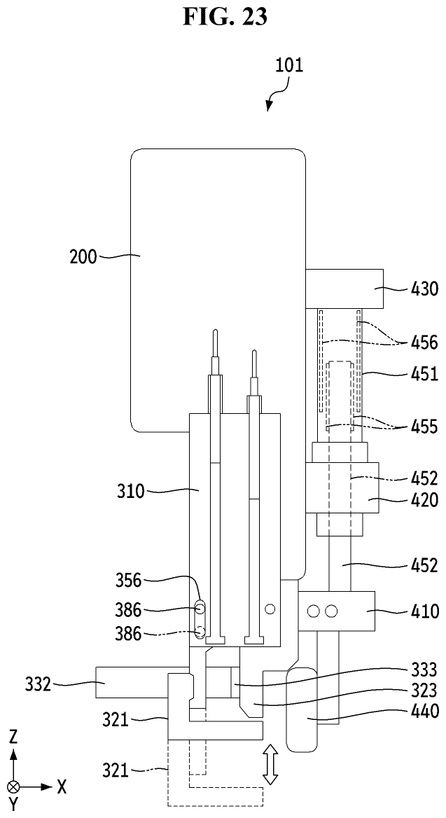

FIG. 23 is a schematic side view of a first robot arm 101 according to another embodiment.

The first robot arm 101 of FIG. 23 differs from the first robot arm 101 of FIG. 7 in the direction of movement of a lever 321, and will hereinafter be described focusing on this difference.

Referring to FIG. 23, the lever 321 may move vertically (e.g., in the positive or negative Z-axis direction) to move away from or closer to (or even contact) the end portion of a stopper 323. For example, a movement shaft 386 of the lever 321 may be inserted into a guide hole 356 of a body 310. The lever 321 may move vertically (e.g., in the positive or negative Z-axis direction) along the guide hole 356.

The guide hole 356 of the body 310 may extend vertically (e.g., in the positive or negative Z-axis direction).

Thus, the lever 321 may grip a dummy DUM by performing a rectilinear motion rather than a rotational motion.

In an embodiment, in response to a first detection signal, the control unit of the first robot arm 101 may raise the lever 321. For example, the lever 321 may rise toward the stopper 323. For example, the lever 321 may move in the positive Z-axis direction toward the stopper 323.

In an embodiment, in response to a second detection signal, the control unit of the first robot arm 101 may lower the lever 321. For example, the lever 321 may move in the negative Z-axis direction away from the stopper 323.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A dummy removal apparatus for manufacturing a display device, comprising:
a support plate;
a gripper disposed on a side of the support plate; and
a presser disposed on another side of the support plate, wherein
the gripper includes a body and a clamp disposed on the body,
the clamp includes:
a lever rotatably connected to a side of the body; and
a stopper disposed on another side of the body, and
in case that the lever rotates toward the stopper, an end portion of the lever and an end portion of the stopper face each other.

2. The dummy removal apparatus of claim 1, wherein the gripper further includes a separator disposed on a side of the stopper.

3. The dummy removal apparatus of claim 2, wherein the separator includes:
a first extension part;
a second extension part disposed facing the first extension part; and
a connecting part connecting the first and second extension parts.

4. The dummy removal apparatus of claim 3, wherein the lever is rotatably connected to the body between the first and second extension parts.

5. The dummy removal apparatus of claim 1, wherein the gripper further includes a first separator and a second separator facing each other on a side of the stopper.

6. The dummy removal apparatus of claim 1, wherein the clamp further includes a link having a side connected to the body via a rotating shaft and another side connected to the lever.

7. The dummy removal apparatus of claim 1, wherein the presser includes:
a pusher;
a lower body connected to the pusher;
a middle body disposed on the lower body and connected to the support plate;
an upper body on the middle body; and
a pressure providing part disposed between the upper body and the lower body, penetrating the middle body, and connecting the upper body and the lower body.

8. The dummy removal apparatus of claim 7, wherein the pressure providing part includes:
a housing having an end portion connected to the upper body and another end facing the lower body through the middle body; and
a movable part having an end portion disposed in the housing and another end connected to the lower body.

9. The dummy removal apparatus of claim 7, wherein the pusher is rotatably connected to the lower body via a rotating shaft of the pusher.

10. The dummy removal apparatus of claim 9, wherein
the lever is connected to the body via a rotating shaft of the lever,
a rotating shaft of the pusher is connected to the lower body, and
the rotating shaft of the lever and the rotating shaft of the pusher intersect each other.

11. The dummy removal apparatus of claim 9, wherein
the lever is connected to the body via a rotating shaft of the lever,
a rotating shaft of the pusher is connected to the lower body, and
the rotating shaft of the lever and the rotating shaft of the pusher are parallel to each other.

12. The dummy removal apparatus of claim 7, wherein the pusher has a cylindrical shape.

13. The dummy removal apparatus of claim 7, wherein the presser further includes a sensor module that detects changes in a distance between the middle body and the lower body.

14. The dummy removal apparatus of claim 13, wherein the sensor module includes:
a sensor connected to the middle body; and
a blocking part having a side connected to the lower body and another side extending toward a light-emitting part and a light-receiving part of the sensor.

15. The dummy removal apparatus of claim 1, wherein the lever has a rotation range of about 0 to about 90 degrees.

16. The dummy removal apparatus of claim 1, wherein the lever has an L-shape.

17. The dummy removal apparatus of claim 1, wherein an end portion of the lever and an end portion of the stopper facing each other have an uneven pattern.

18. The dummy removal apparatus of claim 1, wherein the lever includes a plurality of finger parts.

19. The dummy removal apparatus of claim 18, wherein in case that the lever rotates toward the stopper, end portions of the finger parts of the lever and an end portion of the stopper face each other.

20. A dummy removal apparatus for manufacturing a display device, comprising:
a support plate;
a gripper disposed on a side of the support plate; and
a presser disposed on another side of the support plate, wherein
the gripper includes a body and a clamp disposed on the body,
the clamp includes: a lever connected to the body and moving in a rectilinear direction; and a stopper disposed on another side of the body, and
in case that the lever rises toward the stopper, an end portion of the lever and an end portion of the stopper face each other.

21. A dummy removal method using a dummy removal apparatus for manufacturing a display device, the dummy removal apparatus comprising a robot arm including:
a support plate;
a gripper disposed on a side of the support plate and including a body and a clamp disposed on the body, the clamp including:
a lever rotatably connected to a side of the body, and
a stopper disposed on another side of the body; and
a presser disposed on another side of the support plate,
the dummy removal method comprising:
positioning the robot arm on a stage where a base panel is disposed;
lowering the robot arm toward the base panel to bring the presser into contact with a display panel of the base panel;
rotating the lever toward the stopper to grip a dummy of the base panel between the lever and the stopper via the clamp; and
raising the robot arm to separate the display panel and the dummy, in case that the display panel is pressed by the presser.

22. The dummy removal method of claim 21, further comprising:
before the raising the robot arm, horizontally moving the robot arm in a direction intersecting a direction in which to raise the robot arm, in case that the dummy is gripped.

23. The dummy removal method of claim 22, wherein
the robot arm includes a plurality of robot arms, and
at least two of the robot arms move in different horizontal directions.
